(19) United States
(12) Patent Application Publication
(10) Pub. No.: US 2006/0015801 A1
(43) Pub. Date: Jan. 19, 2006

(54) Method for encoding and decoding error correction block

(75) Inventors: Sang Woon Suh, Seoul (KR); Jin Yong Kim, Kyunggi-Do (KR); Jae Jin Lee, Seoul (KR); Jun Lee, Seoul (KR); Young Ki Kim, Seoul (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 11/185,851

(22) Filed: Jul. 21, 2005

Related U.S. Application Data
(63) Continuation of application No. PCT/KR04/00076, filed on Jan. 17, 2004.

(30) Foreign Application Priority Data
Jan. 21, 2003 (KR) 10-2003-0004079
Jan. 21, 2003 (KR) 10-2003-0004080
Jan. 21, 2003 (KR) 10-2003-0004081

(51) Int. Cl. G06F 11/00; H03M 13/00

(52) U.S. Cl. 714/804

(57) ABSTRACT

The present invention relates to a method for encoding and decoding an error correction block, and more particularly to a method for encoding and decoding an error correction block useful for a high-density optical disc. When an error correction block is encoded, a user data block is generated and parity outer information for a vertical data stream within the user data block is generated. Then, parity inner information is generated using an eraser detection code contained in a horizontal data stream or at least one of a syndrome check parity, a sync byte and an indicator flag is generated within the user data block so that an eraser can be declared in the horizontal data stream at a predetermined internal. On the other hand, when the error correction block is decoded, a determination is made as to whether errors are detected from the eraser detection code, the syndrome check parity, etc., and erasers are declared according to a result of the determination.

### 1. TECHNICAL FIELD

The present invention relates to a method for encoding and decoding an error correction code (ECC) block, and more particularly to a method for encoding and decoding an optimum error correction code (ECC) block for an optical recording medium, e.g., the next generation high-density optical disc, that has a higher recoding density than a digital versatile disc (DVD).

### 2. BACKGROUND ART

Now, the following description will be given on the basis of an optical recording medium such as a high-density optical disc.

An error correction code (ECC) appropriate for a conventional digital versatile disc (DVD) uses a Reed-Solomon (RS) code. A data block in the DVD contains information in which an inner code constituted by RS (182, 172, 11) is interleaved with an outer code constituted by RS (192, 208, 17). Five errors can be corrected by the inner code, and eight errors can be corrected by the outer code.

As shown in FIG. 1, one ECC block contains user data of scrambled “172×192” bytes, and 16 parity outer code (PO) rows, and parity inner code (PI) columns of 10 bytes added to the user data. The ECC block consists of code words of “182×208” bytes.

Furthermore, the code words included in the ECC block have a format in which the 16 PO rows are interleaved with each of 12 inner code words as shown in FIG. 2. A total of 208 inner code words are constituted by 16 sectors, and one sector is constituted by 13 inner code words. Thus, the ECC block includes the 16 sectors, one sector includes the 13 inner code words, and one inner code word includes 182 bytes.

However, where horizontally or vertically consecutive burst errors are incurred within the ECC block of the DVD format constituted as described above, error correction capability is significantly degraded and hence user data cannot be appropriately recovered. In particular, in case of the next generation optical disc having a higher recording density than the DVD, there is a problem in that an error correction operation cannot be performed due to burst errors.

### 3. DISCLOSURE OF INVENTION

Therefore, the present invention has been made in view of the above problems, and it is one object of the present invention to provide a method for encoding and decoding an error correction code (ECC) block of a high-density optical disc that can minimize an error correction failure due to burst errors although horizontally or vertically consecutive burst errors are incurred in the next generation high-density optical disc having a higher recording density than a digital versatile disc (DVD).

It is another object of the present invention to provide a method for encoding and decoding an error correction code (ECC) block of a high-density optical disc that can efficiently prevent an error correction failure due to a random error present within the ECC block in the next generation high-density optical disc having a higher recording density than a digital versatile disc (DVD).

It is yet another object of the present invention to provide a method for encoding and decoding an error correction code (ECC) block of a high-density optical disc that can simplify encoding and decoding operations in the next generation high-density optical disc having a higher recording density than a digital versatile disc (DVD).

In accordance with one aspect of the present invention, the above and other objects can be accomplished by the provision of a method for encoding an error correction code (ECC) block, comprising the steps of: (a) generating a user data block having a predetermined size; and (b) generating a parity outer code (PO) for a vertical data stream and generating a parity inner code (PI) for a horizontal data stream, in the user data block, wherein the user data block contains at least one column of eraser detection codes (ERDCs) so that erasers can be set or declared for the horizontal data stream at a predetermined interval.

In accordance with another aspect of the present invention, the above and other objects can be accomplished by the provision of a method for decoding an error correction code (ECC) block, comprising the steps of: (a) detecting locations in which errors are incurred in a horizontal data stream using a parity inner code (PI) of the ECC block; (b) setting or declaring an eraser when the detected errors are consecutively incurred in eraser detection codes (ERDCs) in a corresponding data stream at a predetermined interval; and (c) performing an error correction operation for a vertical data stream using a parity outer code (PO) of the ECC block, referring to location information associated with the set or declared erasers, and selectively declaring that the error correction operation is impossible.

In accordance with another aspect of the present invention, the above and other objects can be accomplished by the provision of a method for encoding an error correction code (ECC) block, comprising the steps of: (a) generating a user data block having a predetermined size; and (b) generating a parity outer code (PO) for a vertical data stream of the user data block, and generating at least one syndrome check parity (SCP) in the user data block so that erasers can be set or declared in a horizontal data stream at a predetermined interval.

In accordance with another aspect of the present invention, the above and other objects can be accomplished by the provision of a method for decoding an error correction code (ECC) block, comprising the steps of: (a) detecting syndrome check values of a plurality of syndrome check parities (SCPs) contained in a horizontal data stream of the ECC block at a predetermined interval; (b) setting or declaring an eraser, where errors in which the detected check values are not zero are consecutively detected in the SCPs; and (c) performing an error correction operation for a vertical data stream using a parity outer code (PO) of the ECC block, referring to location information associated with the set or declared erasers, and selectively declaring that the error correction operation is impossible.

In accordance with another aspect of the present invention, the above and other objects can be accomplished by the provision of a method for decoding an error correction code (ECC) block, comprising the steps of: (a) detecting syndrome check values of a plurality of syndrome check parities (SCPs) and values of sync bytes contained in a horizontal data stream of the ECC block at a predetermined interval; (b) setting or declaring an eraser, where errors in which the detected syndrome check values are not zero are consecutively detected in the SCPs, or where an error in which the detected sync byte value does not have a preset unique value and an error in which one of the detected syndrome check values is not zero are consecutively incurred; and (c) performing an error correction operation for a vertical data stream using a parity outer code (PO) of the ECC block, referring to location information associated with the set or declared erasers, and selectively declaring that the error correction operation is impossible.

In accordance with another aspect of the present invention, the above and other objects can be accomplished by the provision of a method for encoding an error correction code (ECC) block, comprising the steps of: (a) generating a user data block having a predetermined size; and (b) generating a parity outer code (PO) for a vertical data stream of the user data block, and generating at least one indicator flag (IP) in the user data block so that erasers can be set or declared in a horizontal data stream at a predetermined interval.

In accordance with yet another aspect of the present invention, the above and other objects can be accomplished by the provision of a method for decoding an error correction code (ECC) block, comprising the steps of: (a) detecting values of a plurality of indicator flags (Ifs) contained in a horizontal data stream of the ECC block at a predetermined interval; (b) setting or declaring an eraser, where errors in which the detected IF values are not a preset fixed value are consecutively detected in the IFs; and (c) performing an error correction operation for a vertical data stream using a parity outer code (PO) of the ECC block, referring to location information associated with the set or declared erasers, and selectively declaring that the error correction operation is impossible.

### 4. BRIEF DESCRIPTION OF DRAWINGS

The accompanying drawings, which are included to provide a further understanding of the invention, illustrate the preferred embodiments of the invention, and together with the description, serve to explain the principles of the present invention.

FIGS. 1 and 2 are explanatory views illustrating the format of an error correction code (ECC) block of a conventional digital versatile disc (DVD);

FIG. 3 is a conceptual block diagram illustrating an encoder to which a method for encoding an ECC block in accordance with the present invention is applied;

FIG. 4 is an explanatory view illustrating the format of an ECC block of a high-density optical disc to be encoded and decoded in accordance with the first embodiment of the present invention;

FIG. 5 is a conceptual block diagram illustrating a decoder to which a method for decoding an ECC block in accordance with the present invention is applied;

FIGS. 6 and 7 are detailed explanatory views illustrating the format of the ECC block of the high-density optical disc to be encoded and decoded in accordance with the first embodiment of the present invention;

FIGS. 8 to 10 are explanatory views illustrating the format of an ECC block of the high-density optical disc to be encoded and decoded in accordance with the second embodiment of the present invention;

FIGS. 11 to 13 are explanatory views illustrating the format of an ECC block of the high-density optical disc to be encoded and decoded in accordance with the third embodiment of the present invention;

FIGS. 14 to 16 are explanatory views illustrating the format of an ECC block of the high-density optical disc to be encoded and decoded in accordance with the fourth embodiment of the present invention; and

FIGS. 17 to 19 are explanatory views illustrating the format of an ECC block of the high-density optical disc to be encoded and decoded in accordance with the fifth embodiment of the present invention.

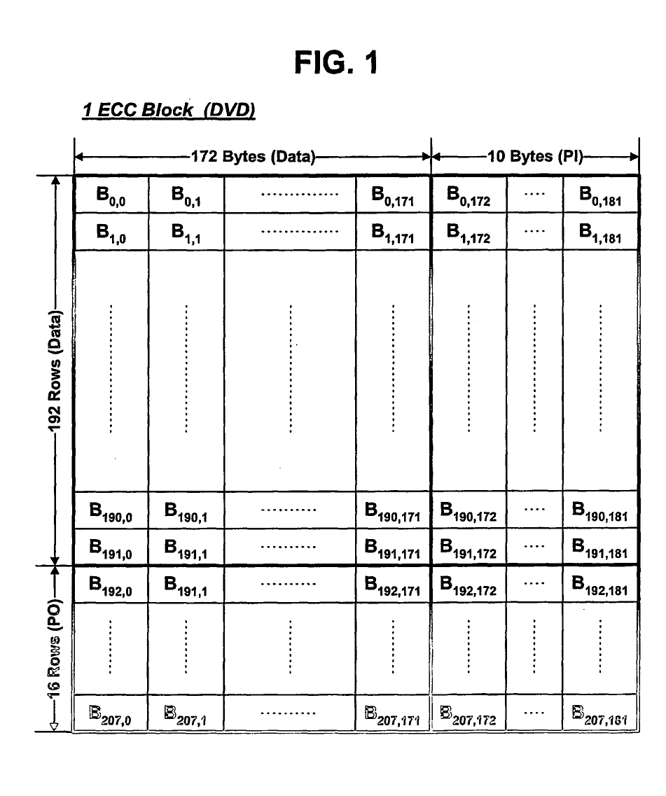

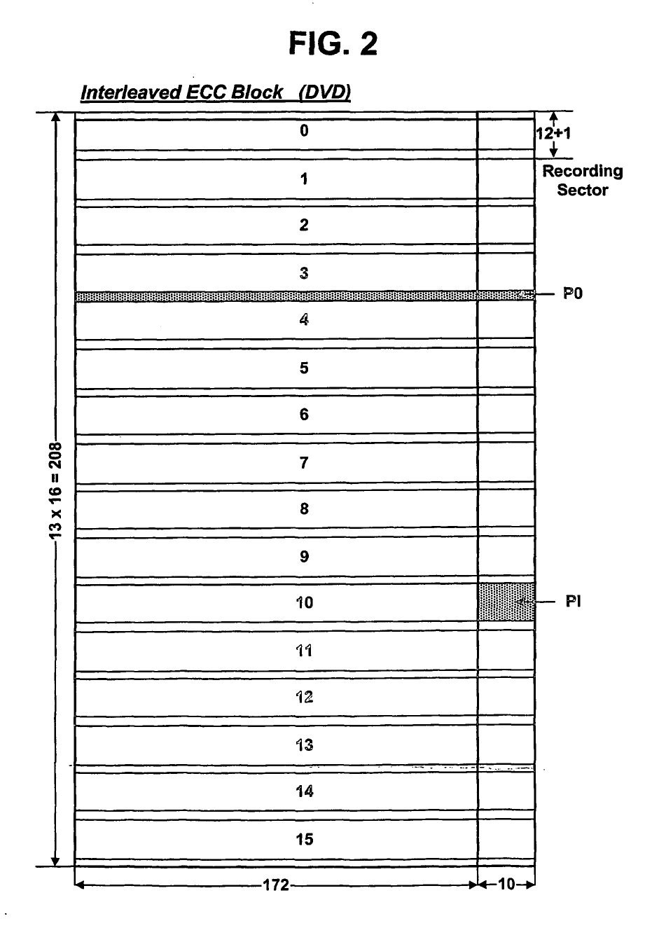

Features, elements, and aspects of the invention that are referenced by the same numerals in different figures represent the same, equivalent, or similar features, elements, or aspects in accordance with one or more embodiments.

### 5. MODES FOR CARRYING OUT THE INVENTION

A method for encoding and decoding an error correction code (ECC) block of a high-density optical disc in accordance with referred embodiments of the present invention will be described in detail with reference to the annexed drawings.

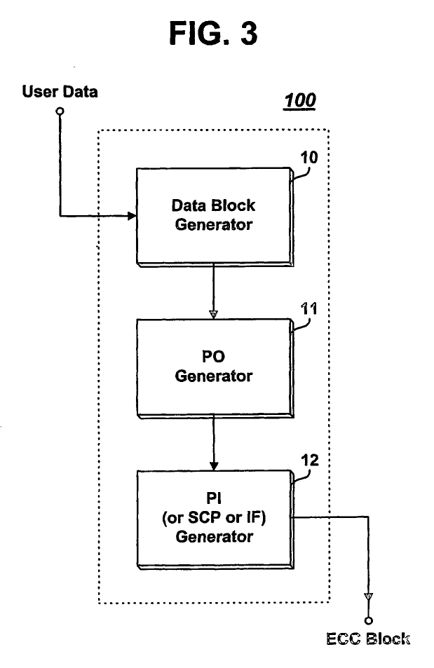

FIG. 3 is a conceptual block diagram illustrating an encoder 100 to which a method for encoding an ECC block in accordance with the present invention is applied. The encoder 100 can include a data block generator 10 for generating a data block having a predetermined size from inputted user data; a parity outer code (PO) generator 11 for generating a PO for the data block; and a parity inner code (PI) generator 12 for generating a PI for the data block. The PI generator 12 can be constituted by a syndrome check parity (SCP) generator for generating an SCP for the data block in accordance with the second to fourth embodiments to be described below, or can be constituted by an indicator flag (IF) generator for generating an IF so that an eraser declaration operation for the data block can be carried out in accordance with the fifth embodiment to be described below.

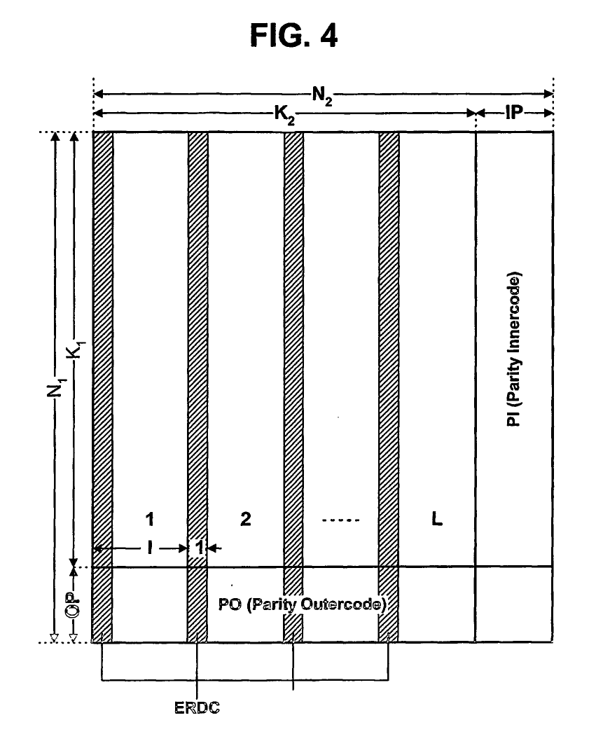

As shown in FIG. 4, the encoder 100 encodes the user data and generates an ECC block having a size of “N₁×N₂” bytes. An eraser detection code (ERDC) value is subtracted from a user data block of “K₁×K₂” bytes. A result of the subtraction is divided by the size of ““N₃×N₂” bytes containing the PO of “OP” bytes and the PI of “IP” bytes. A code rate of the ECC block is a result of the division, i.e., “((K₁×K₂)−ERDC)/(N₁×N₂))”.

Furthermore, the maximum error correction capability of the ECC block corresponds to “N₂×OP” bytes. An error correction operation based on the ECC block is carried out by means of an inner code constituted by RS (L+IP, L, IP+1) and an outer code constituted by RS (N₁, K₁, N₁−K₁+1) in the ECC block.

The encoder 100 generates the user data block of “K₁×K₂” bytes, generates a PO of “OP” (=N₁−K₁) bytes for vertical “K₁” bytes according to RS (N₁, K₁, N₁−K₁+1), and generates a PI of “IP” (=N₂−K₂) bytes for ERDCs of “L”-bytes hatched at a horizontal “I”-byte interval based on RS (L+IP, L, IP+1) as shown in FIG. 4.

The “I”-byte interval can be set to an arbitrary byte interval so that a code rate of the ECC block can be controlled. The final ECC block having the size of the “N₁×N₂” bytes is sequentially read on the basis of a horizontal data stream.

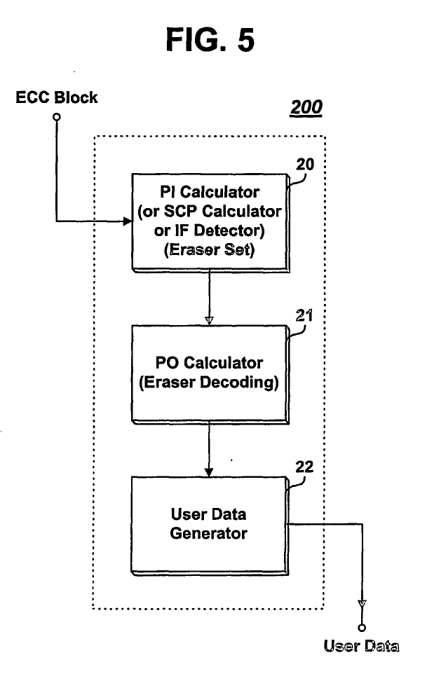

FIG. 5 is a conceptual block diagram illustrating a decoder to which a method for decoding an error correction code (ECC) block in accordance with the present invention is applied. The decoder 200 includes a parity inner coder (PI) calculator 20 for receiving a data stream read on the basis of a horizontal data stream to constitute the ECC block, and setting or declaring erasers after performing an error detection operation using the horizontal data stream and a PI; a parity outer code (PO) calculator 21 for performing an eraser decoding operation using location information of the set or declared erasers and a PO; and a data block generator 22 for generating a user data block in which an error is corrected by means of the eraser decoding operation. The PI calculator 20 can be constituted by a syndrome check parity (SCP) calculator for performing the error detection operation using an information byte I and an SCP contained in a horizontal data stream in accordance with the second to fourth embodiments to be described below, or can be constituted by an indicator flag (IF) detector for performing an eraser declaration or setting operation for the data block using IFs contained in the horizontal data stream at a predetermined interval in accordance with the fifth embodiment to be described below.

Upon reading the horizontal data stream from the ECC block constituted as described with reference to FIG. 4, the decoder 200 performs a decoding operation based on an inner code using the data stream and PI and sets or declares the existence of an eraser. When consecutive errors are incurred in eraser detection codes (ERDCs) contained in the data stream, the eraser is set or declared for the data stream in which the decoding operation based on a current inner code is carried out.

That is, where the errors are consecutively detected from the ERDCs contained in the data stream on the same line by the decoding operation based on the inner code constituted by RS (L+IP, L, IP+1), an eraser can be set or declared in relation to a predetermined data stream for which the decoding operation based on a current inner code is carried out.

Moreover, the decoder 200 performs an eraser decoding operation based on an outer code using eraser location information units obtained through the above-described operation. The eraser decoding operation based on the outer code is carried out only where “(the number of set or declared erasers)+(2×the number of random errors)” “(N₁−K₁)”. In other cases, the decoder 200 declares that the error correction operation is impossible.

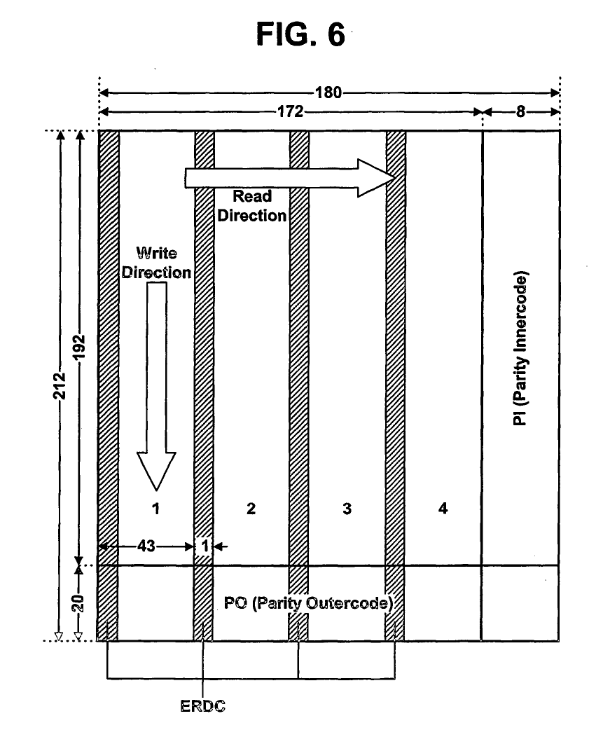

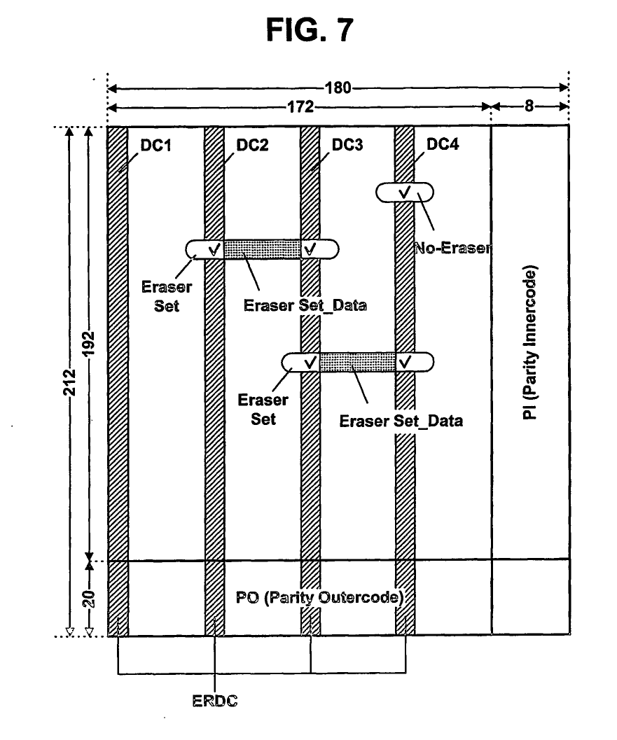

FIGS. 6 and 7 are detailed explanatory views illustrating an error correction code (ECC) block of the high-density optical disc to be encoded and decoded. The ECC block generated by the encoder 100 constituted and operating as described with reference to FIGS. 3 and 4 can have a size of “212×180” bytes. Eraser detection code (ERDC) columns are subtracted from a user data block of “192×172” bytes. A result of the subtraction is divided by the size of “212×180” bytes containing a 20-byte parity outer code (PO) and an 8-byte parity inner code (PI). A code rate of the ECC block is a result of the division, i.e., “0.845”. Where the ERDC columns containing 1-byte EPDCs are constituted by true user data, a code rate of the ECC block is “0.865” by dividing the user data block of “192×172” bytes by the total ECC block of “212×180” bytes.

Furthermore, the maximum error correction capability of the ECC block is “3,600” bytes. The error correction operation is carried out according to an inner code constituted by RS (12, 4, 9) and an outer code constituted by RS (212, 192, 21) in the ECC block.

The encoder 100 generates vertical 192 bytes and horizontal 172 bytes using a Galois field (GF) (2⁸) to configure a data block. Then, the encoder 100 generates the 20-byte PO for the vertical 192 bytes according to RS (212, 192, 21), and generates the 8-byte PI for four 1-byte ERDCs hatched at a horizontal 43-byte interval based on RS (12, 4, 9) as shown in FIG. 6. The encoder 100 generates the ECC block having the size of “212×180”.

On the other hand, the decoder 200 performs a decoding operation based on RS (12, 4, 9) when a horizontal data stream is sequentially received from the ECC block, and confirms location information units indicating where errors are incurred from the data stream.

Furthermore, where the confirmed errors are consecutively incurred in the ERDCs contained in the data stream on the same line as shown in FIG. 7, an eraser is set or declared in relation to an information block between ERDCs. Here, a data column (DC), as an ERDC column, contained in a data stream constitutes true user data.

On the other hand, where the errors are consecutively incurred in the second ERDC column DC2 and the third ERDC column DC3 on the same line on the basis of a horizontal data stream as an example, the decoder 200 sets or declares the eraser. Where an error is incurred only in the fourth ERDC column DC4, no eraser is set or declared.

Furthermore, the decoder 200 performs an eraser decoding operation based on the outer code using eraser location information units acquired from the above-described operation. The eraser decoding operation based on the outer code is carried out only where “(the number of set or declared erasers)+(2× the number of random errors)” “20”. In other cases, the decoder 200 declares that the error correction operation is impossible.

Accordingly, the size of a block associated with the decoding operation based on an inner code is reduced, and hence a time period required for performing the decoding operation is reduced. Furthermore, the method of the present invention is immune to a burst error owing to the decoding operation and the eraser setting or declaration on a block-by-block basis. As the number of PO bytes increases, the maximum error correction capability can be further improved.

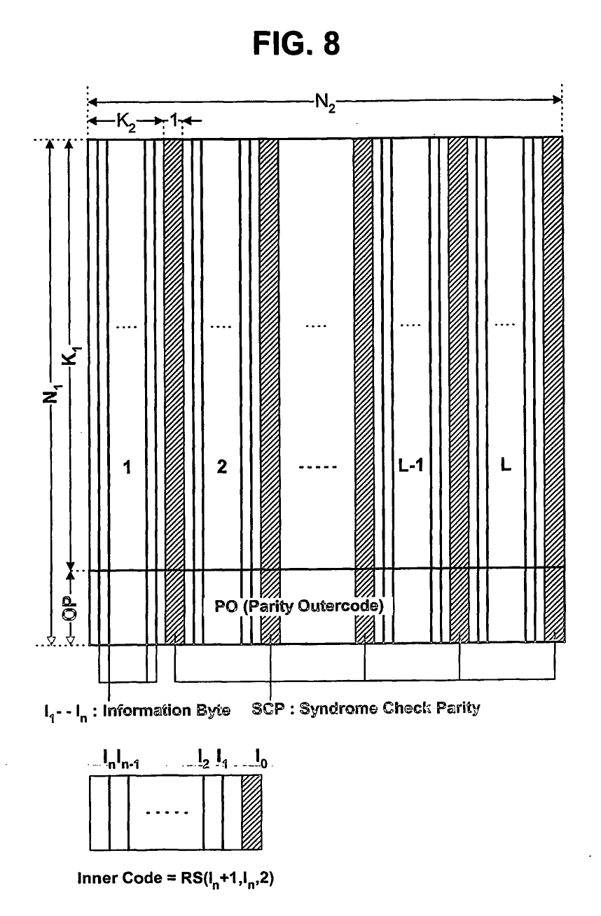

FIGS. 8 to 10 are explanatory views illustrating an error correction code (ECC) block of the high-density optical disc to be encoded and decoded in accordance with the second embodiment of the present invention.

As shown in FIG. 8, the encoder 100 including the data block generator 10, the PO generator 11 and the SCP generator 12 for generating a syndrome check parity (SCP) for the data block, encodes user data and generates the ECC block having a size of “N₁×N₂” bytes. A code rate of the ECC block is “K₁×(K₂×L)/(N₁×N₂)” by dividing “K₁×(K₂×L)” bytes by “N₁×N₂” bytes containing the PO of “OP” bytes and the SCP.

Furthermore, the maximum error correction capability of the ECC block corresponds to “N₂×OP” bytes. An error correction operation is carried out for an inner code constituted by RS (Iₙ+1, Iₙ, 2) and an outer code constituted by RS (N₁, K₁, N₁−K₁+1) in the ECC block.

The encoder 100 constitutes a data block consisting of vertical “K₁” bytes and horizontal “(K₂×L)” bytes. As shown in FIG. 8, the encoder 100 generates a PO of “OP” (=N₁−K₁) bytes for the vertical “K₁” bytes according to RS (N₁, K₁, N₁−K₁+1), and generates 1-byte SCPs using “n” information byte (Iₙ) columns selected within the data block containing “K₂” bytes according to RS (Iₙ+1, Iₙ, 2).

The number of “Iₙ” bytes is an important factor capable of determining the error correction capability in relation to a random error and a burst error. For example, when the number of “Iₙ” bytes is equal to the number of “K₂” bytes, the error detection capability increases but the error correction capability decreases. The number of “K₂” bytes can be variably adjusted so that the code rate can be adjusted.

The interval between information bytes I₁−Iₙ and the number of information bytes I₁−Iₙ within the data block containing the “K₂” bytes can be variably adjusted so that the SCPs can be generated. The final ECC block having the size of “N₁×N₂” bytes is sequentially read on the basis of a horizontal data stream.

On the other hand, where the decoder 200 constituted by the SCP calculator 20, the PO calculator 21 and the data block generator 22 reads the horizontal data stream constituted as described with reference to FIG. 8, a syndrome check operation based on an inner code constituted by RS (Iₙ+1, Iₙ, 2) is performed using a data stream of “K₂+1” bytes. After the syndrome check operation is repeated “L” times in relation to the horizontal data stream, it is determined that an error of a corresponding data block has been detected when a syndrome check value is not zero, and it is determined that no error of a corresponding data block has been detected when a syndrome check value is zero.

If errors are consecutively detected in SCPs contained in the data stream on the same line as a result of the determination, an eraser is set or declared in relation to the data stream for which the decoding operation is performed on the basis of a current syndrome check operation.

That is, where the errors detected by the syndrome check operation based on the inner code constituted by RS (Iₙ+1, Iₙ, 2) are consecutively incurred in the SCPs contained in the data stream on the same line, an eraser is set or declared between a current SCP and a previous or subsequent SCP.

Furthermore, the decoder 200 performs an eraser decoding operation based on the outer code using eraser location information units acquired from the above-described operation. The eraser decoding operation based on the outer code is performed only where “(number of set or declared erasers)+(2×number of random errors)” “(N₁−K₁)”. In other cases, the decoder 200 declares that the error correction operation is impossible.

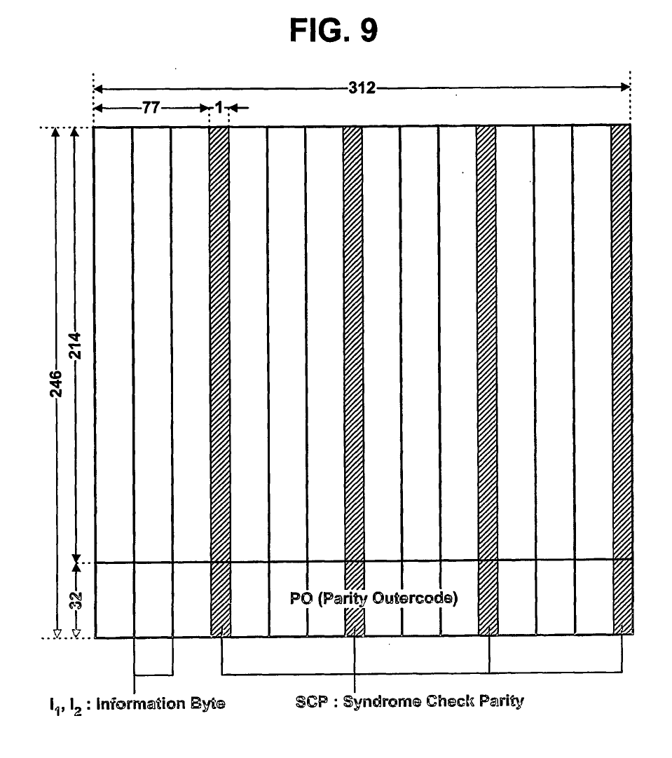

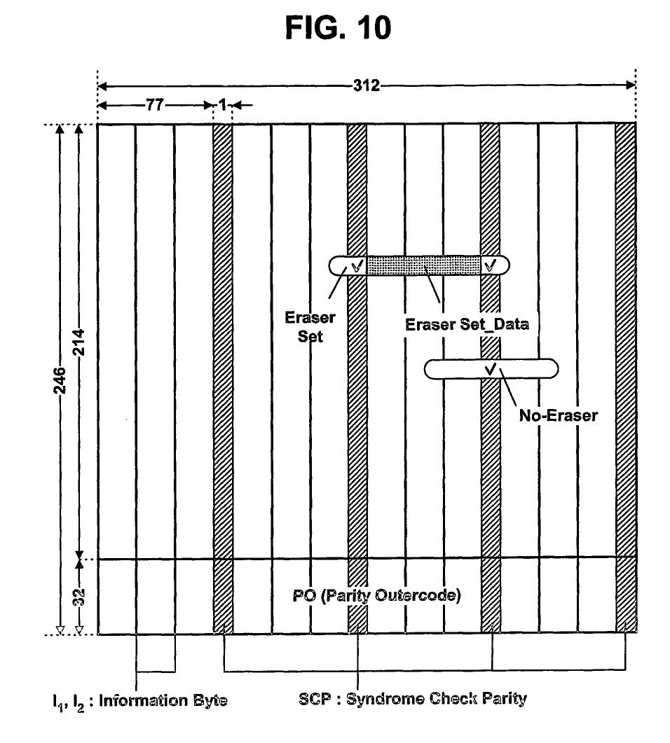

FIGS. 9 and 10 are detailed explanatory views illustrating an ECC block of the high-density optical disc to be encoded and decoded in accordance with the second embodiment of the present invention. The ECC block generated by the encoder 100 constituted and operating as described with reference to FIGS. 3 and 8 can have a size of “246×312” bytes. In this case, a code rate of the ECC block corresponds to “0.859” and the maximum error correction capability corresponds to “9,984” bytes. The error correction operation is carried out by means of an inner code constituted by RS (3, 2, 2) and an outer code constituted by RS (246, 214, 33) in the ECC block.

The encoder 100 generates vertical 214 bytes and horizontal 308 bytes using a Galois field (GF) (2⁸) to configure a data block. Then, the encoder 100 generates a 32-byte PO for the vertical 214 bytes according to RS (246, 214, 33), and repeatedly generates an SCP of 1 byte for 2 information bytes (I) by means of the inner code constituted by RS (3, 2, 2) four times, such that the encoder 100 generates the ECC block having the size of “246×312” bytes.

On the other hand, when sequentially receiving a horizontal data stream of the ECC block, the decoder 200 determines whether a syndrome check value is zero using a total of 3 bytes containing the 2 information bytes and the 1-byte SCP in the data stream containing 78 (77+1) bytes, that is, whether an error is detected. At this point, the syndrome check operation for the horizontal data stream is repeated four times, and hence erasers are set or declared.

For example, where errors are consecutively detected in SCPs contained in the data stream on the same line after the syndrome check operation for the horizontal data stream is repeated four times as shown in FIG. 10, an eraser is set or declared in relation to an information block between the SCPs. Where an error is incurred only in one SCP, no eraser is set or declared.

Furthermore, the decoder 200 performs the eraser decoding operation based on the outer code using eraser location information units acquired from the above-described operation. The eraser decoding operation based on the outer code is carried out only where “(the number of set or declared erasers)+(2× the number of random errors)” “32”. In other cases, the decoder 200 declares that the error correction operation is impossible.

Accordingly, a decoding operation is simple because erasers are set or declared using only the syndrome check operation, and a time period required for performing the decoding operation is reduced because the number of data units configuring the inner code is reduced. Furthermore, the method of the present invention is immune to a burst error owing to the decoding operation and the eraser setting or declaration on a block-by-block basis. As the number of PO bytes increases, the error correction capability can be improved.

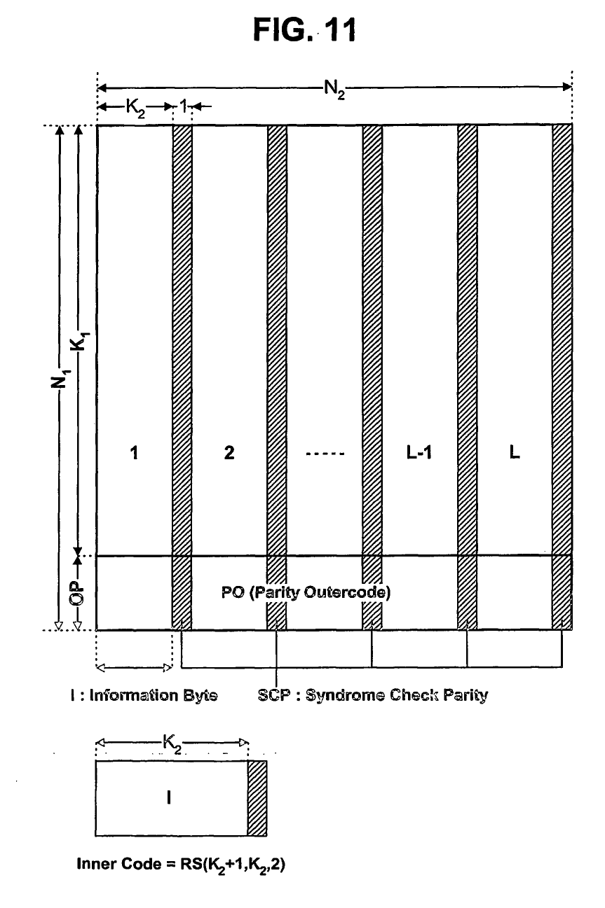

FIGS. 11 to 13 are explanatory views illustrating an error correction code (ECC) block of the high-density optical disc to be encoded and decoded in accordance with the third embodiment of the present invention. The ECC block generated in accordance with the third embodiment of the present invention has a same size and a code rate described with reference to FIG. 8. Furthermore, the encoder 100 repeats an operation for generating an SCP of 1 byte for a data block containing “K₂” bytes “L” times. In this case, the encoder 100 generates 1-byte SCPs using all information bytes (I) consecutively contained in the data block containing “K₂” bytes.

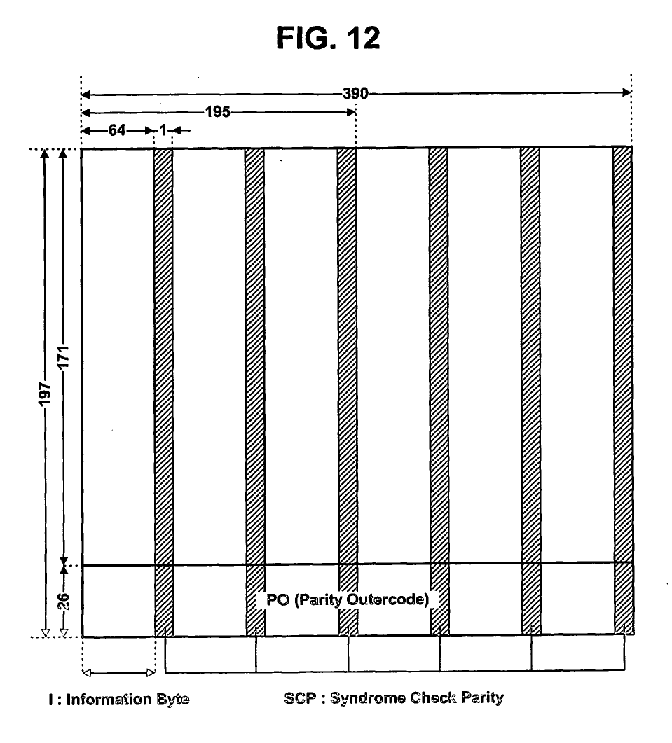

The number of “K₂” bytes can be variably adjusted so that the code rate can be adjusted. The final ECC block having a size of “N₁×N₂” bytes is sequentially read on the basis of a horizontal data stream. For example, an ECC block generated by the encoder 100 can have a size of “197×390” bytes as shown in FIG. 12. In this case, a code rate of the ECC block corresponds to “0.855”, a size of the data block corresponds to “65,664” bytes, and the maximum error correction capability corresponds to “10,140” bytes. The error correction operation is carried out according to an inner code constituted by RS (65, 64, 2) and an outer code constituted by RS (197, 171, 27) in the ECC block.

Furthermore, the encoder 100 generates vertical 171 bytes and horizontal 384 bytes to configure a data block. As shown in FIG. 12, the encoder 100 generates a 26-byte PO for the vertical 171 bytes by means of an outer code based on RS (197, 171, 27) and repeatedly generates an SCP of 1 byte for 64 information bytes (I) by means of the inner code constituted by RS (65, 64, 2) six times, such that the encoder 100 generates the ECC block having a size of “197×390” bytes.

On the other hand, when sequentially receiving a horizontal data stream of the ECC block, the decoder 200 determines whether a syndrome check value is zero using a total of 65 bytes containing the 64 information bytes and the 1-byte SCP, that is, whether an error is detected. At this point, the syndrome check operation for the horizontal data stream is repeated six times, and hence erasers are set or declared.

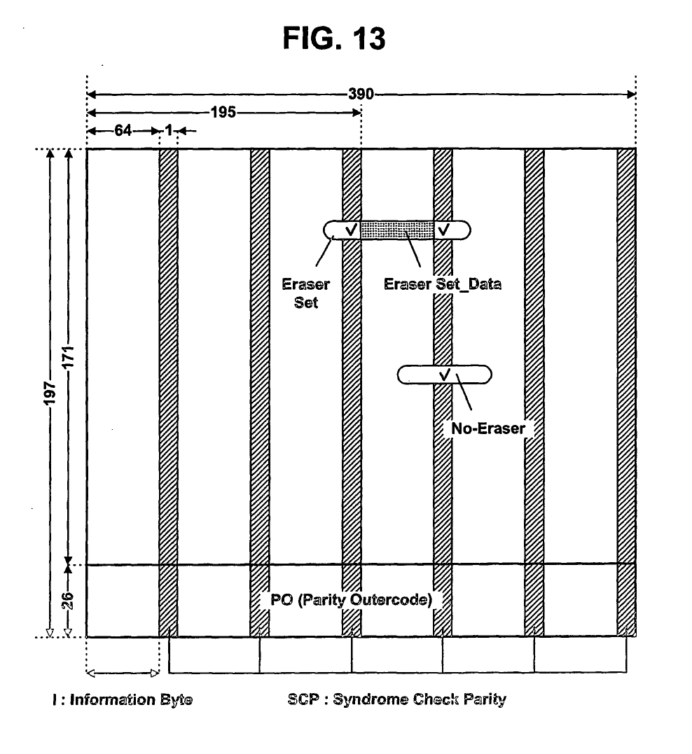

For example, where errors are consecutively incurred in SCPs contained in the data stream on the same line after the syndrome check operation for a horizontal data stream is repeated six times as shown in FIG. 13, an eraser is set or declared in relation to an information block between the SCPs. Where an error is incurred only in one SCP, no eraser is set or declared.

Furthermore, the decoder 200 performs an eraser decoding operation based on the outer code using eraser location information units obtained through the above-described operation. The eraser decoding operation based on the outer code is carried out only where “(the number of set or declared erasers)+(2× the number of random errors)” “26”. In other cases, the decoder 200 declares that the error correction operation is impossible.

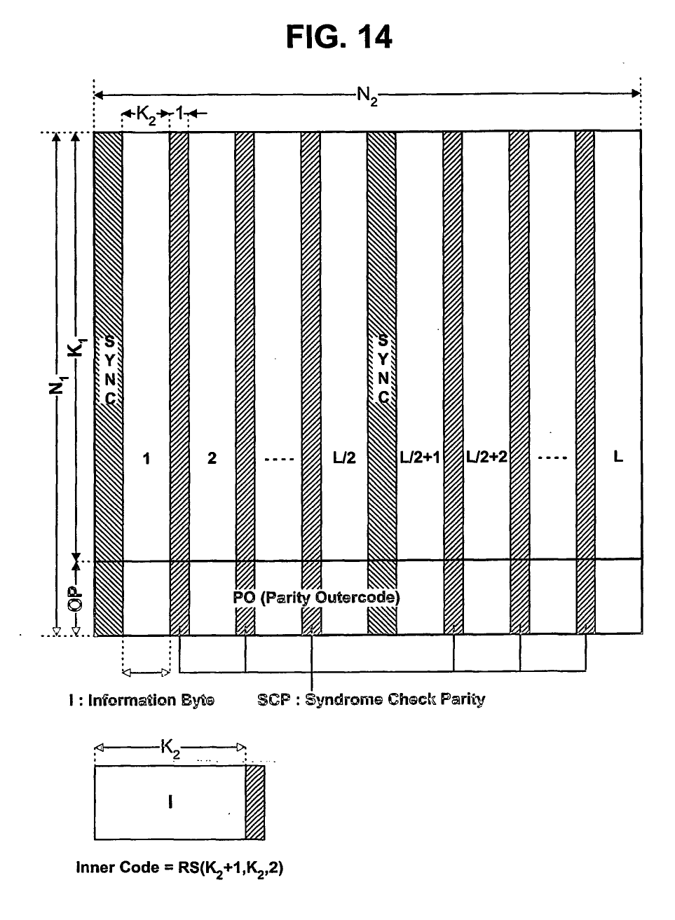

FIGS. 14 to 16 are explanatory views illustrating an error correction code (ECC) block of the high-density optical disc to be encoded and decoded in accordance with the fourth embodiment of the present invention. The encoder 100 records SCPs necessary for setting or declaring an eraser within a user data block while generating an ECC block having a size of “N₁×N₂” bytes as described with reference to FIG. 8. As shown in FIG. 14, sync bytes to be used for setting or declaring erasers are contained in the user data block at a predetermined interval, and the sync bytes have a fixed value of more than one byte.

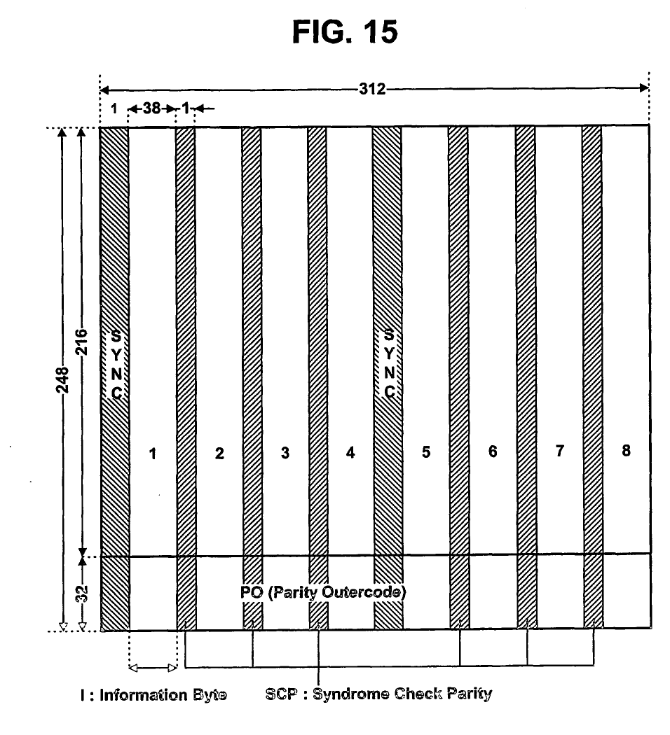

As shown in FIG. 15, the ECC block can have a size of “248×312” bytes. In this case, a code rate of the ECC block corresponds to “0.849”, a size of the data block corresponds to “65,664” bytes, and the maximum error correction capability corresponds to “9,920” bytes. The error correction operation is carried out according to an inner code constituted by RS (39, 38, 2) and an outer code constituted by RS (248, 216, 33) in the ECC block.

Furthermore, the encoder 100 generates vertical 216 bytes and horizontal 304 bytes to configure a data block. As shown in FIG. 15, the encoder 100 generates a 32-byte PO for the vertical 216 bytes by means of an outer code of RS (248, 216, 33), and generates sync bytes having fixed values in lead-in and middle regions in the horizontal direction. The encoder 100 repeatedly generates a 1-byte SCP at a 38-byte interval by means of an inner code of RS (39, 38, 2) six times, such that the encoder 100 generates the ECC block having a size of “242×312” bytes.

On the other hand, when sequentially receiving a horizontal data stream of the ECC block, the decoder 200 determines whether a syndrome check value is zero using a total of 39 bytes containing information and SCP bytes, that is, whether an error is detected, by means of the inner code of RS (39, 38, 2). Furthermore, the decoder determines whether sync bytes are detected as the fixed values. At this point, the syndrome and sync byte check operations are performed, and hence erasers are set or declared.

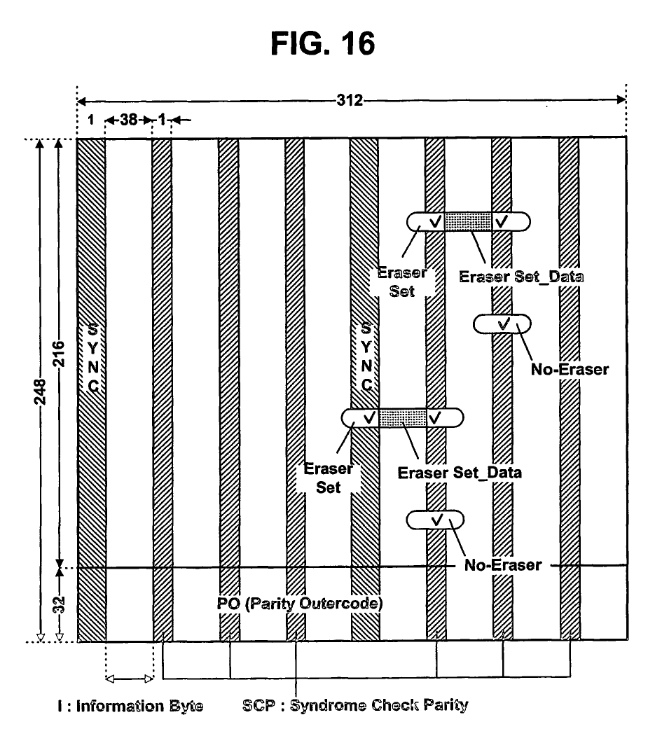

For example, where errors are consecutively detected in SCPs contained in the data stream on the same line as shown in FIG. 16, an eraser is set or declared in relation to an information block between the SCPs. Where an error is incurred only in one SCP, no eraser is set or declared.

Where the sync byte is not detected as a preset fixed value and an error is incurred in an SCP adjacent to the sync byte, an eraser for an information block between the sync byte and the SCP is set or declared.

Furthermore, the decoder 200 performs an eraser decoding operation based on the outer code using eraser location information units acquired from the above-described operation. The eraser decoding operation based on the outer code is carried out only where “(number of set or declared erasers)+(2×number of random errors)” “32”. In other cases, the decoder 200 declares that the error correction operation is impossible.

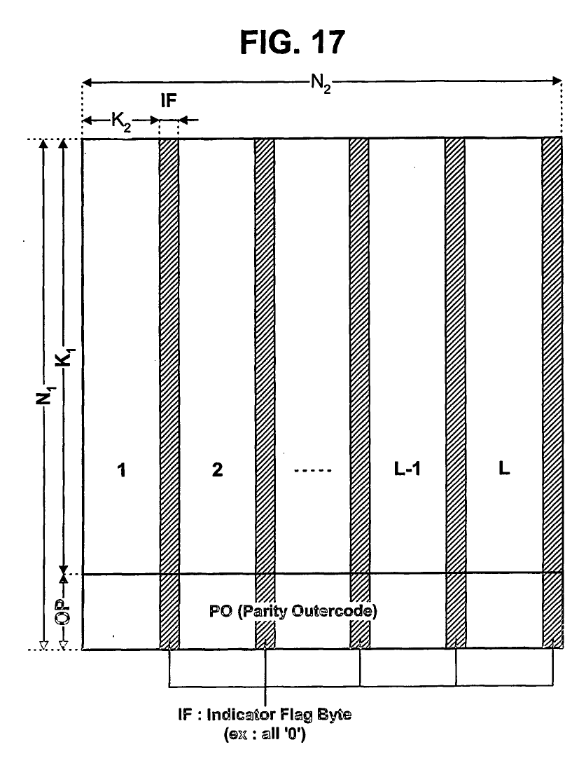

FIGS. 17 to 19 are explanatory views illustrating an error correction code (ECC) block of the high-density optical disc to be encoded and decoded in accordance with the fifth embodiment of the present invention.

As shown in FIG. 17, the encoder 100 including the data block generator 10, the PO generator 11 and an indicator flag (IF) generator 12 for generating an indicator flag (IF) so that an eraser declaration operation for the data block can be carried out, encodes user data and generates the ECC block having a size of “N₁×N₂” bytes. A code rate of the ECC block is “K₁×(K₂×L)/(N₁×N₂)” by dividing “K₁×(K₂×L)” bytes by “N₁×N₂” bytes containing the PO of “OP” bytes and the IF of predetermined bytes.

Furthermore, the maximum error correction capability of the ECC block corresponds to “N₂×OP” bytes. The erasers are declared by means of the IF, and an outer code constituted by RS (N₁, K₁, N₁−K₁+1) in the ECC block.

The encoder 100 constitutes a data block consisting of vertical “K₁” bytes and horizontal “(K₂×L)” bytes. As shown in FIG. 17, the encoder 100 generates a PO of “OP” (=N₁−K₁) bytes for the vertical “K₁” bytes according to RS (N₁, K₁, N₁−K₁+1), and repeatedly generates a 1-byte IF having a preset fixed value (e.g. “0”) at a “K₂”-byte interval IL” times.

The IF has not the error correction capability but only the error detection capability. The number of “K₂” bytes can be variably adjusted so that the code rate can be adjusted. And, the final ECC block having the size of “N₁×N₂” bytes is sequentially read on the basis of a horizontal data stream.

On the other hand, where the decoder 200 constituted by the IF detector 20, the PO calculator 21 and the data block generator 22 sequentially receives the horizontal data stream constituted as described with reference to FIG. 17, the decoder 200 performs an IF detection operation. After the IF detection operation is repeated “L” times in relation to the horizontal data stream, it is determined that an error of a corresponding data block has been detected when an IF detection value is not zero, and it is determined that no error of a corresponding data block has been detected when a IF detection value is zero.

If errors are consecutively detected in IFs contained in the data stream on the same line as a result of the determination, an eraser is set or declared in relation to the data stream for which the decoding operation is performed on the basis of a current IF detection operation.

Furthermore, the decoder 200 performs an eraser decoding operation based on the outer code using eraser location information units acquired from the above-described operation. The eraser decoding operation based on the outer code is performed only where “(number of set or declared erasers)+(2×number of random errors)” “(N₁−K₁)”. In other cases, the decoder 200 declares that the error correction operation is impossible.

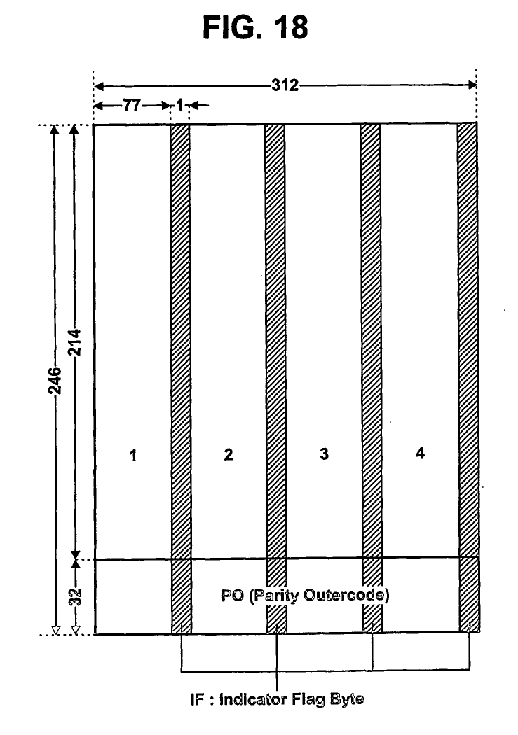

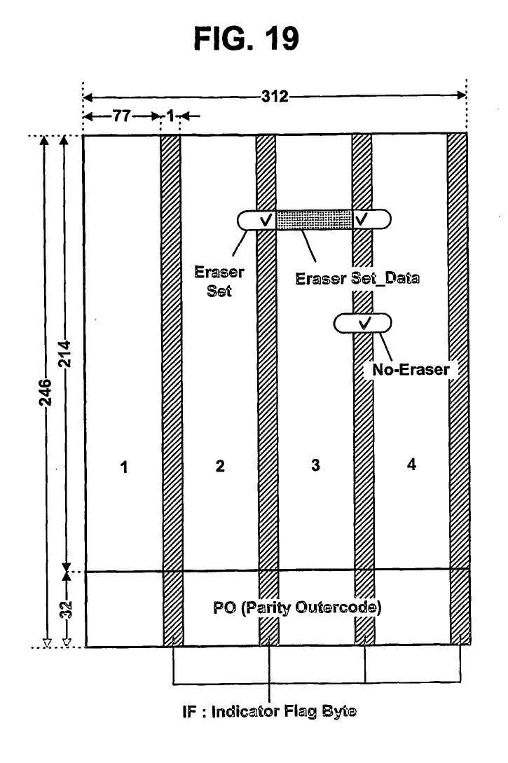

FIGS. 18 and 19 are detailed explanatory views illustrating an ECC block of the high-density optical disc to be encoded and decoded in accordance with the fifth embodiment of the present invention. The ECC block generated by the encoder 100 constituted and operating as described with reference to FIGS. 3 and 17 can have a size of “246×312” bytes. In this case, a code rate of the ECC block corresponds to “0.859”, a size of the data block corresponds to “65,912” bytes, and the maximum error correction capability corresponds to “9,984” bytes. The error correction operation is carried out by means of an outer code constituted by RS (246, 214, 33) in the ECC block.

The encoder 100 generates vertical 214 bytes and horizontal 308 bytes to configure a data block. Then, the encoder 100 generates a 32-byte PO for the vertical 214 bytes according to RS (246, 214, 33), and repeatedly generates a 1-byte IF of “0” at a horizontal 77-byte interval 4 times, such that the encoder 100 generates the ECC block having the size of “246×312” bytes.

On the other hand, when sequentially receiving a horizontal data stream of the ECC block, the decoder 200 determines whether the If in a interval of 78 bytes containing the 77 information bytes and the 1-byte IF is detected as a preset fixed value, for example “0”, that is, whether an error is detected.

For example, where errors are consecutively detected in IFs contained in the data stream on the same line by means of the IF detection operation for the horizontal data stream as shown in FIG. 19, an eraser is set or declared in relation to an information block between the IFs. Where an error is incurred only in one IF, no eraser is set or declared.

Furthermore, the decoder 200 performs the eraser decoding operation based on the outer code of RS (246, 214, 33) using eraser location information units acquired from the above-described operation. The eraser decoding operation based on the outer code is carried out only where “(the number of set or declared erasers)+(2×the number of random errors)” “32”. In other cases, the decoder 200 declares that the error correction operation is impossible.

Accordingly, a decoding operation is simple because erasers are set or declared only by checking the IF values, and the method of the present invention is immune to a burst error owing to the decoding operation and the eraser setting or declaration on a block-by-block basis. As the number of PO bytes increases, the error correction capability can be improved.

For reference, the IF can be assigned to another fixed value rather than “0”, and can be equal to or more than one byte.

As apparent from the above description, the present invention provides a method for encoding and decoding an error correction code (ECC) block that can minimize an error correction failure due to burst errors although horizontally or vertically consecutive burst errors are incurred in the next generation high-density optical disc having a higher recording density, that can efficiently prevent an error correction failure due to a random error, that can reduce a time period required for the encoding and decoding operations, and that can improve the maximum error correction capability.

Although the present invention has been described in connection with specific preferred embodiments, those skilled in the art will appreciate that various modifications, additions, and substitutions to the specific elements are possible, without departing from the scope and spirit of the present invention as disclosed in the accompanying claims.

1. A method for encoding an error correction code (ECC) block, comprising the steps of:
(a) generating a user data block having a predetermined size; and
(b) generating a parity outer code (PO) for a vertical data stream and generating a parity inner code (PI) for a horizontal data stream, in the user data block,
wherein the user data block contains at least one column of eraser detection codes (ERDCS) so that erasers can be set or declared for the horizontal data stream at a predetermined interval.

2. The method as set forth in claim 1, wherein the ERDCs are true user data.

3. The method as set forth in claim 1, wherein the PO is generated according to RS (N₁, K₁, N₁−K₁+1) determined by the number of vertical “N₁,” bytes in the ECC block having a size of “N₁×N₂” bytes and the number of vertical “K₁” bytes in the user data block having a size of “K₁×K₂” bytes, such that the generated PO corresponds to the number of “N₁−K₁” bytes.

4. The method as set forth in claim 1, wherein the PI is generated using the ERDCs and data stream, such that the generated PI corresponds to the number of “N₂−K₂” bytes indicating a difference between the number of horizontal “N₂” bytes in the ECC block having a size of “N₁×N₂” bytes and the number of horizontal “K₂” bytes in the user data block having a size of “K₁×K₂” bytes.

5. The method as set forth in claim 4, wherein the ERDCs have a size of one byte, respectively, and are contained in the horizontal data stream at a predetermined interval, and wherein the PI is generated using the ERDCs.

6. The method as set forth in claim 5, wherein the PI is generated according to RS (L+IP, L, IP+1) determined by “L” number of ERDCs and “IP” number of PI bytes contained in the horizontal data stream.

7. A method for decoding an error correction code (ECC) block, comprising the steps of:
(a) detecting locations in which errors are incurred in a horizontal data stream using a parity inner code (PI) of the ECC block;
(b) setting or declaring an eraser when the detected errors are consecutively incurred in eraser detection codes (ERDCs) contained in a corresponding data stream at a predetermined interval; and
(c) performing an error correction operation for a vertical data stream using a parity outer code (PO) of the ECC block, referring to location information associated with the set or declared erasers, and selectively declaring that the error correction operation is impossible.

8. The method as set forth in claim 7, wherein the step (b) comprises the step of:
declaring no eraser when the detected errors are not consecutively incurred in the ERDCs in the corresponding data stream.

9. The method as set forth in claim 7, wherein that the error correction operation is impossible is declared if “(the number of set or declared erasers)+(2×the number of random errors)” “(the number of vertical PO bytes)” is not satisfied.

10. A method for encoding an error correction code (ECC) block, comprising the steps of:
(a) generating a user data block having a predetermined size; and
(b) generating a parity outer code (PO) for a vertical data stream of the user data block, and generating at least one syndrome check parity (SCP) in the user data block so that erasers can be set or declared in a horizontal data stream at a predetermined interval.

11. The method as set forth in claim 10, wherein the step (b) comprises the step of:
generating at least one sync byte in the user data block so that the erasers can be set or declared in the horizontal data stream at the predetermined interval, in place of part of the generated at least one SCP.

12. The method as set forth in claim 11, wherein the sync byte indicates a preset unique value.

13. The method as set forth in claim 10, wherein the PO is generated according to RS (N₁, K₁, N₁−K₁+1) determined by the number of vertical “N₁” bytes in the ECC block having a size of “N₁×N₂” bytes and the number of vertical “K₁” bytes in the user data block having a size of “K₁×K₂” bytes, such that the generated PO corresponds to the number of “N₁−K₁” bytes.

14. The method as set forth in claim 10, wherein the at least one SCP is generated using a plurality of information bytes intermittently contained in the predetermined interval of the horizontal data stream, respectively, and wherein the number of the generated at least one SCP corresponds to the number of the predetermined intervals.

15. The method as set forth in claim 10, wherein the at least one SCP is generated using a plurality of information bytes consecutively contained in the predetermined interval of the horizontal data stream, respectively, and wherein the number of the generated at least one SCP corresponds to the number of the predetermined intervals.

16. The method as set forth in claim 14 or 15, wherein the SCP is generated by RS (Iₙ+1, Iₙ, 1+1) determined by “Iₙ” number of information bytes contained in the predetermined interval and one syndrome check byte.

17. A method for decoding an error correction code (ECC) block, comprising the steps of:
(a) detecting syndrome check values of a plurality of syndrome check parities (SCPs) contained in a horizontal data stream of the ECC block at a predetermined interval;
(b) setting or declaring an eraser, where errors in which the detected check values are not zero are consecutively detected in the SCPs; and
(c) performing an error correction operation for a vertical data stream using a parity outer code (PO) of the ECC block, referring to location information associated with the set or declared erasers, and selectively declaring that the error correction operation is impossible.

18. The method as set forth in claim 17, wherein the step (b) comprises the step of:
declaring no eraser when an error is detected only in one SCP in the corresponding data stream.

19. The method as set forth in claim 17, wherein that the error correction operation is impossible is declared if “(the number of set or declared erasers)+(2×the number of random errors)”≦“(the number of vertical PO bytes)” is not satisfied.

20. A method for decoding an error correction code (ECC) block, comprising the steps of:
(a) detecting syndrome check values of a plurality of syndrome check parities (SCPs) and values of sync bytes contained in a horizontal data stream of the ECC block at a predetermined interval;
(b) setting or declaring an eraser, where errors in which the detected syndrome check values are not zero are consecutively detected in the SCPs, or where an error in which the detected sync byte value does not have a preset unique value and an error in which one of the detected syndrome check values is not zero are consecutively incurred; and
(c) performing an error correction operation for a vertical data stream using a parity outer code (PO) of the ECC block, referring to location information associated with the set or declared erasers, and selectively declaring that the error correction operation is impossible.

21. The method as set forth in claim 20, wherein the step (b) comprises the step of:
declaring no eraser when an error is incurred only in one SCP or sync byte in the corresponding data stream.

22. The method as set forth in claim 20, wherein that the error correction operation is impossible is declared if “(the number of set or declared erasers)+(2×the number of random errors)”≦“(the number of vertical PO bytes)” is not satisfied.

23. A method for encoding an error correction code (ECC) block, comprising the steps of:
(a) generating a user data block having a predetermined size; and
(b) generating a parity outer code (PO) for a vertical data stream of the user data block, and generating at least one indicator flag (IF) in the user data block so that erasers can be set or declared in a horizontal data stream at a predetermined interval.

24. The method as set forth in claim 23, wherein the PO is generated according to RS (N₁, K₁, N₁−K₁+1) determined by the number of vertical “N₁” bytes in the ECC block having a size of “N₁×N₂” bytes and the number of vertical “K₁” bytes in the user data block having a size of “K₁×K₂” bytes, such that the generated PO corresponds to the number of “N₁−K₁” bytes.

25. The method as set forth in claim 23, wherein the IF indicates a preset unique value of equal to or more than one byte, and wherein the number of the generated at least one IF corresponds to the number of the predetermined intervals.

26. The method as set forth in claim 25, wherein the generated at least IF is “0” of one byte, respectively.

27. A method for decoding an error correction code (ECC) block, comprising the steps of:
(a) detecting values of a plurality of indicator flags (Ifs) contained in a horizontal data stream of the ECC block at a predetermined interval;
(b) setting or declaring an eraser, where errors in which the detected IF values are not a preset fixed value are consecutively detected in the IFs; and
(c) performing an error correction operation for a vertical data stream using a parity outer code (PO) of the ECC block, referring to location information associated with the set or declared erasers, and selectively declaring that the error correction operation is impossible.

28. The method as set forth in claim 27, wherein the step (b) comprises the step of:
declaring no eraser when an error is detected only in one IF in the corresponding data stream.

29. The method as set forth in claim 27, wherein that the error correction operation is impossible is declared if “(the number of set or declared erasers)+(2×the number of random errors)”≦“(the number of vertical PO bytes)” is not satisfied.
